(19) United States
(12) Patent Application Publication
(10) Pub. No.: US 2025/0266660 A1
(43) Pub. Date: Aug. 21, 2025

(54) LASER POWER STABILITY CONTROL VIA THERMAL INSTABILITY COMPENSATION

(71) Applicant: Lumentum Operations LLC, San Jose, CA (US)

(72) Inventors: Matthew KUTSURIS, Dublin, CA (US); Gary BURKHOLDER, San Jose, CA (US); Guan SUN, San Jose, CA (US); Borja FONS, Zurich (CH); Abel GONZALEZ, Zurich (CH); Jiho HAN, Zurich (CH)

(21) Appl. No.: 18/804,496

(22) Filed: Aug. 14, 2024

Related U.S. Application Data
(60) Provisional application No. 63/554,665, filed on Feb. 16, 2024.

(51) Int. Cl. H01S 5/0683; H01S 5/04; H01S 5/042; H01S 5/068

(52) U.S. Cl. CPC H01S 5/06835; H01S 5/041; H01S 5/0428; H01S 5/06808; H01S 5/06837

(57) ABSTRACT

A laser system may include a compensation component to receive a control signal indicating a target output power of an output laser pulse to be provided by the laser system, and generate a compensated current signal based on the control signal. The compensated current signal may be generated to reduce a difference between the target output power of the laser pulse and an actual output power of the laser pulse over a period of time during the laser pulse. The laser system may include a diode pump drive circuit to generate a drive current based on the compensated current signal. The laser system may include a diode pump module to generate pump light based on the drive current. The laser system may include an optical output to provide the output laser pulse.

### CROSS-REFERENCE TO RELATED APPLICATION

This patent application claims priority to U.S. Provisional Patent Application No. 63/554,665, filed on Feb. 16, 2024, and entitled “LASER POWER STABILITY CONTROL VIA THERMAL COMPENSATION.” The disclosure of the prior Application is considered part of and is incorporated by reference into this patent application.

### TECHNICAL FIELD

The present disclosure relates generally to a fiber laser and to power stability control of a fiber laser via thermal instability compensation.

### BACKGROUND

A fiber laser is a form of solid-state laser that may be capable of achieving high output power and high beam quality. Typically, a fiber laser is considered to be a laser with an active optical fiber as the laser gain medium. The gain medium may be, for example, a fiber doped with rare earth ions such as erbium (Er³⁺), neodymium (Nd³⁺), ytterbium (Yb³⁺), thulium (Tm³⁺), or praseodymium (Pr³⁺). Although the gain medium of a fiber laser is similar to those of solid-state bulk lasers in terms of operation principles and spectroscopic data, the waveguiding effect and the small effective mode area typically provide different properties. For example, a fiber laser typically operates with higher laser gain and resonator losses. In practice, one or more fiber-coupled laser diodes are used for pumping a fiber laser. Therefore, many fiber lasers are diode-pumped lasers.

### SUMMARY

In some implementations, a laser system includes a compensation component to: receive a control signal indicating a target output power of an output laser pulse to be provided by the laser system, and generate a compensated current signal based on the control signal, wherein the compensated current signal is to reduce a difference between the target output power of the laser pulse and an actual output power of the laser pulse over a period of time during the laser pulse; a diode pump drive circuit to generate a drive current based on the compensated current signal; a diode pump module to generate pump light based on the drive current; and an optical output to provide the output laser pulse.

In some implementations, a laser system includes one or more processors to: receive a control signal indicating a target output power for a laser pulse, and generate a compensated current signal based on the control signal, wherein the compensated current signal is to provide compensation for time-decaying overshoot or undershoot of an actual output power of the laser pulse relative to the target output power of the laser pulse; a diode pump to generate a pump light based on a drive current that corresponds to the compensated current signal; and a master oscillator power amplification (MOPA) system to generate the laser pulse using the pump light.

In some implementations, a method includes receiving, by a compensation component of a high-power laser system, a control signal indicating a target output power of an output laser pulse; determining, by the compensation component, an estimated thermal state associated with the high-power laser system based on a current signal corresponding to the target output power and using a thermal model; calculating, by the compensation component, a thermal instability compensation factor based on the estimated thermal state, wherein the thermal instability compensation factor is calculated in association with providing compensation for output power overshoot or undershoot of the laser pulse over a period of time at a start of the laser pulse; applying, by the compensation component, the thermal instability compensation factor to the current signal to generate a compensated current signal; and providing, by the compensation component, the compensated current signal in association with generation of the laser pulse.

### BRIEF DESCRIPTION OF THE DRAWINGS

FIGS. 1A-1B are diagrams associated with an example implementation of a laser system with power stability control provided via thermal instability compensation as described herein.

FIG. 2 is a diagram illustrating an example implementation of a compensation component as described herein.

FIG. 3 is a flowchart of an example process associated with laser power stability control via thermal instability compensation as described herein.

FIG. 4 is a diagram of example components of a device associated with laser power stability control via thermal instability compensation as described herein.

### DETAILED DESCRIPTION

The following detailed description of example implementations refers to the accompanying drawings. The same reference numbers in different drawings may identify the same or similar elements.

During a cold start of a laser system (e.g., a laser power-on event while diodes of the laser system are at or near an ambient temperature) an output power of a laser pulse provided by the laser system often overshoots (i.e., is greater than) or undershoots (i.e., is less than) a target output power. Generally, this power overshooting or undershooting is present until temperature of the diodes of the laser system stabilize. More particularly, at a time of a power-on event of a laser system, a temperature of a diode is lower than the temperature of the diode at a later time of operation after which the temperature of the diode has stabilized (e.g., after the laser system has been powered on for at least a few seconds). In practice, efficiency of the diode decreases as temperature of the diode increases. This means that efficiency of the diode decreases from the time of the power-on event until the time at which the temperature of the diode is stabilized. After temperature stabilization, the diode efficiency remains relatively constant. The higher diode efficiency during the period of time prior to temperature stabilization means that the power provided by the diode is higher prior to temperature stabilization, which results in power overshooting during the period of time prior to temperature stabilization.

In one example, power overshooting can cause a peak power during modulation to be significantly higher than desired (e.g., between approximately 5% and approximately 15% greater than desired), which results in a smaller margin against unwanted non-linear optical effects, such as stimulated Raman scattering (SRS) or transverse mode instability. A non-linear optical effect such as an SRS causes a wavelength of an output of the laser system to be converted to a comparatively longer wavelength, which can increase instability of the laser system, shift an optical spectrum of the output (e.g., a shift of approximately 55 nanometers (nm) in a 1080 nm laser), increase fiber heating, reduce efficiency, and/or increase a beam parameter product (BPP) of the output of the laser system. Further, power overshooting can cause catastrophic damage to, for example, a fiber amplifier of the laser system as a result of SRS buildup or optical fluence that exceeds a damage threshold of the fiber amplifier or a feed fiber. Additionally, a difference between an actual output power and a target output power (e.g., power undershooting or power overshooting) can, due to the diode wavelength changing with diode temperature, cause output power that is not a square wave and that varies until diode temperatures stabilize, which is undesirable with respect to performance of the laser system. A difference between an actual output power and the target output power being present is especially pronounced in a high-power (e.g., greater than 15 kilowatts (KW)) laser system, where diodes are driven with higher current and result in larger temperature swings of the diodes.

One conventional technique uses thermo-electric coolers (TECs) to promote diode temperature stabilization (e.g., such that power overshooting or undershooting are reduced). However, TECs are infeasible or undesirable in some laser systems, such as high-power laser systems, due to cost and significant additional power needed to drive the TECs. Another conventional technique uses “wavelength locked” diodes to stabilize pump wavelengths (e.g., such that power overshooting or undershooting are reduced). However, the use of wavelength locked diodes is not feasible or undesirable in some laser systems, such as high-power laser systems, due to cost and non-trivial output power reduction of a diode pump module.

Some implementations described herein enable laser power stability control via thermal instability compensation. In some implementations, a laser system may comprise a compensation component configured to receive a control signal indicating a target output power of an output laser pulse to be provided by the laser system. In some implementations, the compensation component may generate a compensated current signal based on the control signal. Here, the compensated current signal may be generated so that a difference between the target output power of the laser pulse and an actual output power of the laser pulse over a period of time during the laser pulse is reduced. In some implementations, the laser system may include a diode pump drive circuit to generate a drive current based on the compensated current signal, a diode pump module to generate pump light based on the drive current, and an optical output to provide the output laser pulse.

In some implementations, the techniques and apparatuses described herein provide temperature instability compensation that mitigates an impact of a cold start of a diode of a laser system, thereby reducing or eliminating a power overshoot or undershoot of the diode. As a result, a likelihood of damage to one or more components of the laser system that could result from power overshooting (or undershooting) is reduced or eliminated (e.g., by preventing SRS buildup or preventing optical fluence from exceeding a damage threshold). Further, the techniques and apparatuses described herein can improve a “shape” of output power of the laser system (e.g., such that an improved square wave is generated), thereby improving performance of the laser system. Additional details are provided below.

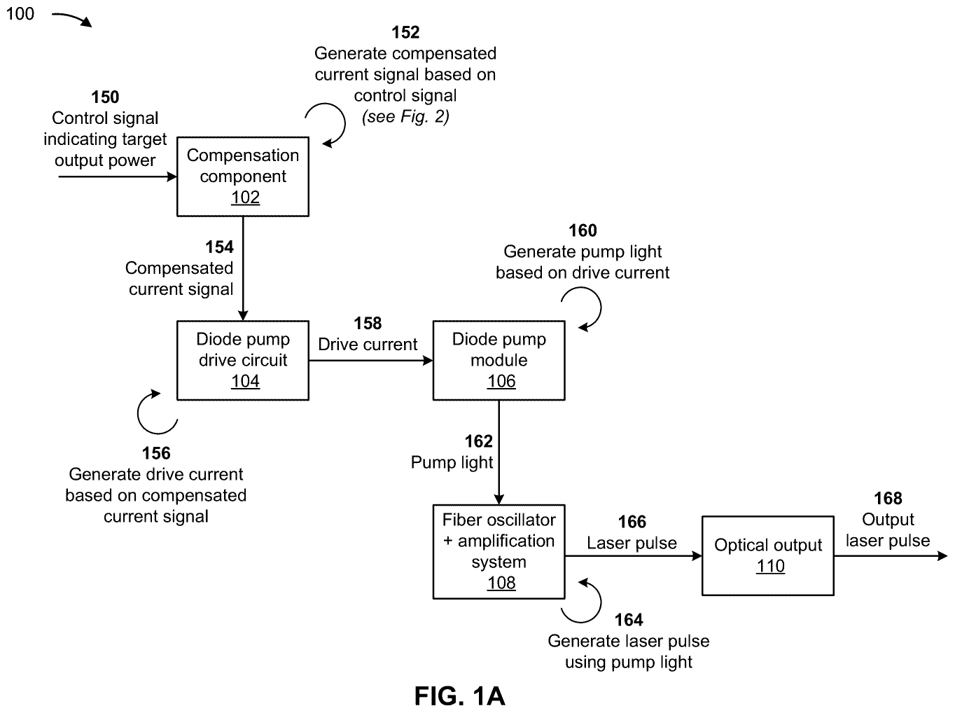

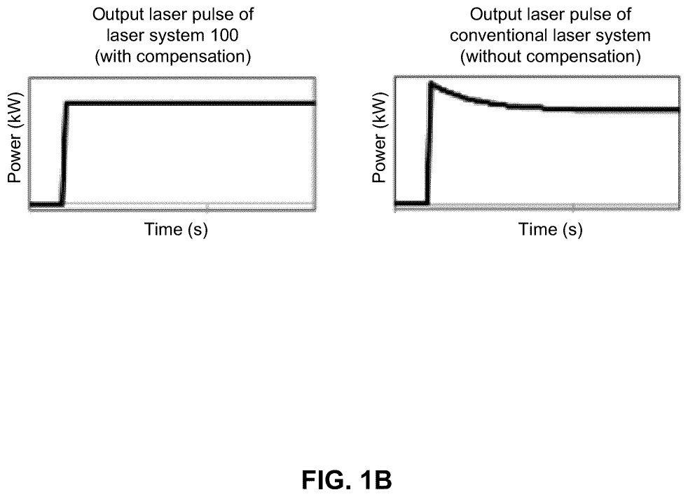

FIGS. 1A-1B are diagrams associated with an example implementation of a laser system 100 with power stability control provided via thermal instability compensation as described herein. In some implementations, the laser system 100 may be a high-power laser system (e.g., a laser system designed to provide at least approximately 15 kW of output power). Additionally, or alternatively, the laser system 100 may be another type of laser system (e.g., a laser system designed to provide output power less than approximately 15 KW). As shown in FIG. 1A, the laser system 100 may include a compensation component 102, a diode pump drive circuit 104, a diode pump module 106, a fiber oscillator and amplification system 108, and an optical output 110. The components of the laser system 100 are described below, followed by a description of an example operation of the laser system 100.

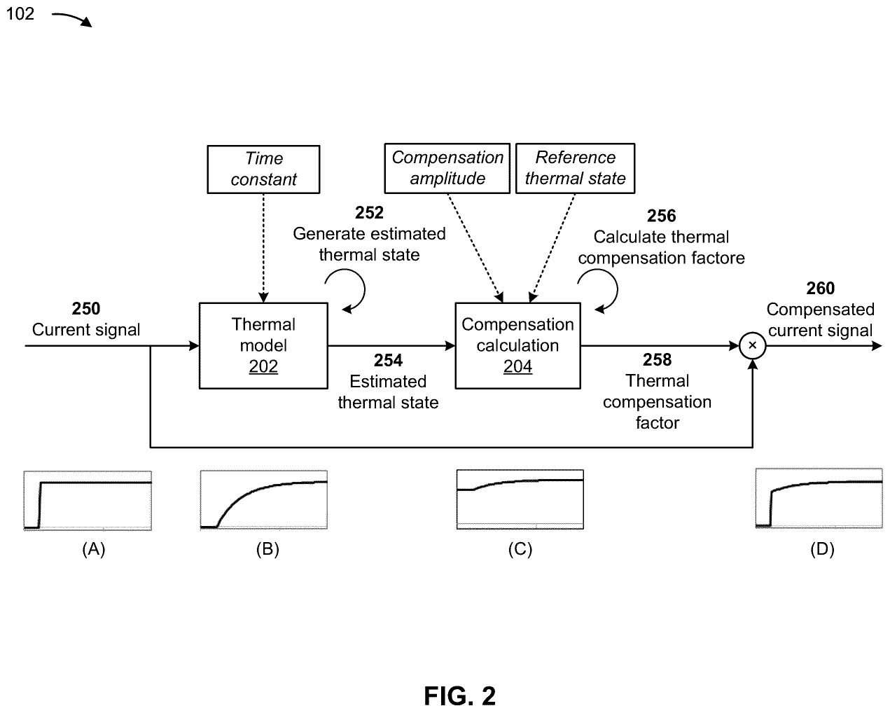

The compensation component 102 includes one or more components capable of generating a compensated current signal associated with reducing a difference between a target output power of a laser pulse of the laser system 100 and an actual output power of the laser pulse over a period of time. For example, the compensated current signal may be used to provide compensation for time-decaying overshoot or undershoot of the actual output power of the laser pulse relative to the target output power of the laser pulse. In some implementations, the compensation component 102 generates the compensated current signal based on a control signal that indicates the target output power of the laser pulse. Additional details regarding the compensation component 102 are provided below with respect to FIG. 2.

The diode pump drive circuit 104 includes one or more components capable of generating a drive current based on the compensated current signal. That is, the diode pump drive circuit 104 may receive the compensated current signal from the compensation component 102, and may generate a current associated with driving the diode pump module 106 based on the compensated current signal.

The diode pump module 106 includes one or more components capable of generating pump light based on the drive current. That is, the diode pump module 106 may receive the drive current generated by the diode pump drive circuit 104, and may drive diodes of the diode pump module 106 in order to generate pump light. In some implementations, the diode pump module 106 comprises a plurality of diodes (e.g., a plurality of edge-emitting lasers optically coupled to a single fiber). In some implementations, the compensated current signal generated by the compensation component 102 provides compensation for time-decaying overshoot or undershoot of the laser pulse resulting from, for example, a thermal state associated with the plurality of diodes of the diode pump module 106.

The fiber oscillator and amplification system 108 includes one or more components capable of generating a laser pulse using the pump light generated by the diode pump module 106. That is, the pump light generated by the diode pump module 106 can be injected into the fiber oscillator and amplification system 108, and the fiber oscillator and amplification system 108 may use the pump light to generate one or more laser pulses. For example, the fiber oscillator and amplification system 108 may in some implementations be a master oscillator and power amplification (MOPA) system.

The optical output 110 includes one or more components capable of providing an output laser pulse (e.g., an output of the laser system 100). That is, the optical output 110 may receive the laser pulse generated by the fiber oscillator and amplification system 108, and may provide the laser pulse as an optical output of the laser system 100.

In an example operation of the laser system 100, starting at reference 150, the compensation component 102 receives a control signal indicating a target output power of an output laser pulse to be provided by the laser system 100. In some implementations, the target output power of the output laser pulse (and one or more other target characteristics of the laser pulse) may be configured or selected by a user of the laser system 100.

As shown at reference 152, the compensation component 102 generates a compensated current signal based on the control signal. As noted above, the compensated current signal may be used to reduce a difference between the target output power of the laser pulse and an actual output power of the laser pulse over a period of time during the laser pulse (e.g., a period of time corresponding to a start of the laser pulse). More particularly, the compensated current signal is generated by the compensation component 102 such that a thermal state (e.g., a temperature, or temperature change) of the diodes of the diode pump module 106 is compensated for so as to reduce or eliminate power overshooting or undershooting the output laser pulse of the laser system 100. Additional details regarding generation of the compensated current signal are provided below with respect to FIG. 2.

As shown at reference 154, the compensation component 102 provides the compensated current signal to the diode pump drive circuit 104 and, as shown at reference 156, the diode pump drive circuit 104 generates a drive current based on the compensated current signal.

As shown at reference 158, the diode pump drive circuit 104 drives the diode pump module 106 using the drive current and, as shown at reference 160, the diode pump module 106 generates pump light based on the drive current.

As shown at reference 162, the diode pump module 106 provides the pump light to the fiber oscillator and amplification system 108 and, as shown at reference 164, the fiber oscillator and amplification system 108 generates a laser pulse using the pump light.

As shown at reference 166, the fiber oscillator and amplification system 108 provides the laser pulse to the optical output 110 and, as shown at reference 168, the optical output 110 provides the laser pulse as an output of the laser system 100.

As described above, compensation for a thermal state or thermal change of diodes of the diode pump module 106 during a period of time of the laser pulse is provided via the compensated current signal generated by the compensation component 102. In this way, a likelihood of damage to one or more components of the laser system 100 that could result from power overshooting (or undershooting) is reduced or eliminated (e.g., by preventing SRS buildup or preventing optical fluence from exceeding a damage threshold) and/or a “shape” of the output power of the laser system 100 is improved (e.g., such that an improved square wave is generated).

FIG. 1B illustrates an example of an impact of compensation as provided by the laser system 100. The left diagram in FIG. 1B illustrates power (in kW) of an output laser pulse of the laser system 100 over time (in seconds) with thermal instability compensation as described above. The right diagram in FIG. 1B illustrates power of an output laser pulse of a conventional laser system (i.e., a laser system that does not provide thermal instability compensation). As can be seen by comparison of the left diagram and the right diagram of FIG. 1B, power overshoot is eliminated in the output laser pulse of the laser system 100, while power overshoot is present in the output laser pulse of the conventional laser system. For example, referring to FIG. 1B, a target power level may be 15 KW for a 976 nm pump diode laser system. An instability (e.g., overshoot and undershoot) of an output pulse's power level by a conventional laser system (without compensation) may have a magnitude of 16% at the start of the pulse which decays (e.g., pump diodes thermally stabilizing) over five seconds. In comparison, a laser system 100 with compensation (e.g., thermal instability compensation as described herein) may avoid power instability and the output pulse power level may equal the target power level for the duration of the pulse.

As indicated above, FIGS. 1A-1B are provided as examples. Other examples may differ from what is described with regards to FIGS. 1A-1B. Further, the number and arrangement of components shown in FIG. 1A are provided as an example. In practice, there may be additional components, fewer components, different components, or differently arranged components than those shown in FIG. 1A. Furthermore, two or more components shown in FIG. 1A may be implemented within a single component, or a single component shown in FIG. 1A may be implemented as multiple, distributed components. Additionally, or alternatively, a set of components (e.g., one or more components) shown in FIG. 1A may perform one or more functions described as being performed by another set of components shown in FIG. 1A.

FIG. 2 is a diagram illustrating an example implementation of a compensation component 102 as described herein. As shown in FIG. 2, the compensation component 102 may include a thermal model 202 and a compensation calculation component 204. Components of the compensation component 102 are described below, followed by a description of an example of operation of the compensation component 102.

The thermal model 202 includes one or more components configured with a model for estimating a thermal state associated with the laser system 100 (e.g., a thermal state of one or more diodes of the diode pump module 106 of the laser system 100). In some implementations, the thermal model models drive current variation over time of a diode with respect to temperature of the diode. In some implementations, the thermal model 202 may receive a current signal as an input and may provide, as an output, an estimated thermal state associated with the laser system 100. The current signal is a signal indicating a current demand associated with driving the diodes of the diode pump module 106. In some implementations, the current signal may correspond to or be determined based on the control signal. For example, the current demand may be a function of the target output power and, therefore, the compensation component 102 may determine the current signal based on the control signal indicating the target output power. The estimated thermal state may indicate, for example, a temperature of one or more diodes of the diode pump module 106 at a given point in time (e.g., over a period of time during a start of a laser pulse). In some implementations, the thermal model determines the estimated thermal state based on a configurable time constant (e.g., a value that defines a time response of the thermal model). In operation, the compensation component 102 uses the thermal model 202 to compensate or correct the drive current over time so as to cause the laser system 100 to provide the output laser pulse having the target output power.

In some implementations, the thermal model 202 may be configured such that thermal state estimation can be provided irrespective of a configuration of an operational parameter associated with the laser system 100. For example, the thermal model 202 may be designed to estimate a thermal state associated with the laser system 100 for an arbitrary current demand and/or an arbitrary output laser pulse duty cycle. Notably, the estimated thermal state, and therefore the associated thermal instability compensation factor, will likely differ for different configurations of such operational parameters. Further, the thermal model 202 may be configured such that thermal state estimation can be perform irrespective of a starting thermal state of the one or more diodes of the laser system 100 (e.g., the thermal model 202 may provide thermal state estimation in scenarios other than a “cold start”). The thermal model 202 may be configured to operate as an open loop, without any feedback.

The compensation calculation component 204 includes one or more components capable of calculating a thermal instability compensation factor based on the estimated thermal state. The thermal instability compensation factor is a factor to be applied to the current signal in association with generating a compensated current signal—the signal based on which the drive current of the diode of the diode pump module 106 is generated. The thermal instability compensation factor can therefore be used to provide compensation for output power overshoot or undershoot of the output laser pulse of the laser system 100 (e.g., over a period of time at a start of the laser pulse). In some implementations, the thermal instability compensation factor may be a value in a range of values (e.g., a value in a range from 0.0 to 1.0). In some implementations, the thermal instability compensation factor may be calculated based on a configurable compensation amplitude. The configurable compensation amplitude may be, for example, a value that defines a maximum amplitude of compensation (e.g., when the laser system 100 in in a “coldest” state). Additionally, or alternatively, the thermal instability compensation factor may be calculated based on a reference thermal state. The reference thermal state may be, for example, a state of the laser system 100 at which no compensation is to be performed. In some implementations, the reference thermal state may be related to a maximum power and/or a maximum current permitted in the laser system 100. The compensation calculation component 204 may be configured to operate as an open loop, without any feedback.

In an example of operation of the compensation component 102, starting at reference 250, the compensation component 102 provides a current signal as an input to the thermal model 202. Here, the current signal corresponds to the target output power indicated by the control signal received by the compensation component 102 as described above with respect to FIG. 1A. In some implementations, the compensation component 102 may determine the current signal based on the control signal. For example, the compensation component 102 may determine the current demand associated with driving the one or more diodes of the diode pump module 106 based on the target output power of the laser pulse as indicated in the control signal. Diagram (A) in the lower portion of FIG. 2 illustrates an example of the current signal over a period of time as provided to the thermal model 202.

As shown at reference 252, the thermal model 202 generates an estimated thermal state associated with the laser system 100 and, as shown at reference 254, provides the estimated thermal state associated with the laser system 100 to the compensation calculation component 204. Diagram (B) in the lower portion of FIG. 2 illustrates an example of the estimated thermal state associated with the laser system 100 over the period of time as determined by the thermal model 202.

As shown at reference 256, the compensation component 102 calculates a thermal instability compensation factor based on the estimated thermal state. As shown at reference 258, the compensation calculation component 204 provides the thermal instability compensation factor such that the thermal instability compensation factor is applied to the current signal (e.g., such that the level of the current signal is multiplied by the thermal instability compensation factor), a result of which is the compensated current signal. Diagram (C) in the lower portion of FIG. 2 illustrates an example of the thermal instability compensation factor associated with the laser system 100 over the period of time as calculated by the compensation calculation component 204.

As shown at reference 260, the compensated current signal is then provided as an output of the compensation component 102 (e.g., such that the diode pump drive circuit 104 generates a drive current based on the compensated current signal as described with respect to FIG. 1A). Diagram (D) in the lower portion of FIG. 2 illustrates an example of the compensation component 102 over the period of time as provided by the compensation component 102 (after the thermal instability compensation factor is applied to the control signal). In this example, the compensated current signal illustrated in diagram (D) results in the output power profile illustrated in the left diagram of FIG. 1B as described above.

In some implementations, as illustrated in FIG. 2, the compensation component 102 may be configured to provide open-loop compensation (e.g., using only the target output power and the thermal model of the diodes). For greater clarity, the compensation component 102 may operate without a thermal measurement or thermal feedback associated with the laser system 100. Alternatively, in some implementations, the compensation component 102 may be configured to provide closed-loop compensation (e.g., by measuring actual temperature of the diodes of the diode pump module or measuring the output of the laser system 100 and providing compensation based on such measurement(s)).

In some implementations, the compensation component 102 may be configured to generate the compensated current signal based on an exponential decay function. Additionally, or alternatively, the compensation component 102 may be configured to generate the compensated current signal based on another type of function, such as a logarithmic function or a linear function. In some implementations, the function based on which the compensation component 102 generates the compensated current signal may be configurable or selectable by a user of the laser system 100.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more functions described as being performed by another set of components shown in FIG. 2.

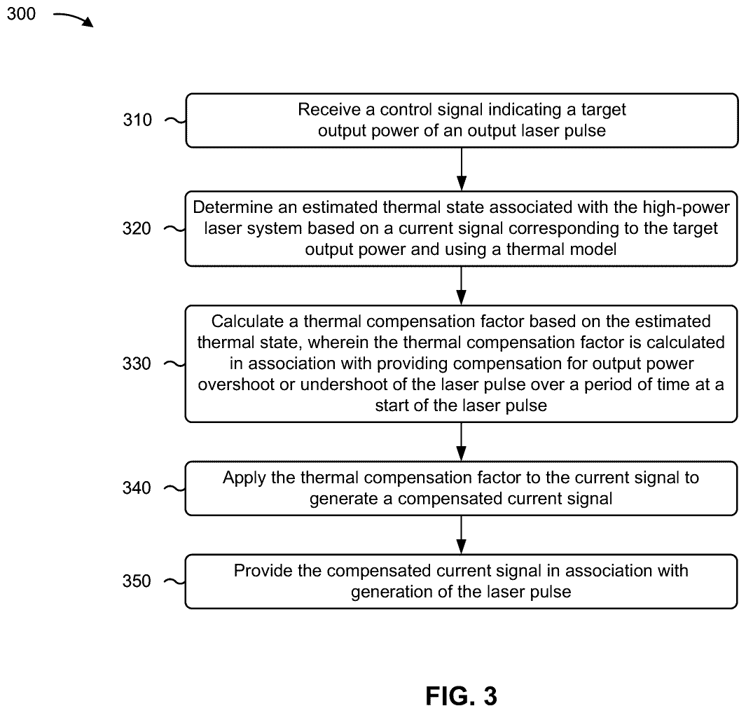

FIG. 3 is a flowchart of an example process 300 associated with laser power stability control via thermal instability compensation. In some implementations, one or more process blocks of FIG. 3 are performed by a compensation component (e.g., compensation component 102). In some implementations, one or more process blocks of FIG. 3 are performed by another device or a group of devices separate from or including the compensation component, such as a thermal model (e.g., thermal model 202) and/or a compensation calculation component (e.g., compensation calculation component 204).

As shown in FIG. 3, process 300 may include receiving a control signal indicating a target output power of an output laser pulse (block 310). For example, the compensation component may receive a control signal indicating a target output power of an output laser pulse, as described above.

As further shown in FIG. 3, process 300 may include determining an estimated thermal state associated with the high-power laser system based on a current signal corresponding to the target output power and using a thermal model (block 320). For example, the compensation component may determine an estimated thermal state associated with a laser system based on a current signal corresponding to the target output power and using a thermal model, as described above.

As further shown in FIG. 3, process 300 may include calculating a thermal instability compensation factor based on the estimated thermal state, wherein the thermal instability compensation factor is calculated in association with providing compensation for output power overshoot or undershoot of the laser pulse over a period of time at a start of the laser pulse (block 330). For example, the compensation component may calculate a thermal instability compensation factor based on the estimated thermal state, wherein the thermal instability compensation factor is calculated in association with providing compensation for output power overshoot or undershoot of the laser pulse over a period of time at a start of the laser pulse, as described above.

As further shown in FIG. 3, process 300 may include applying the thermal instability compensation factor to the current signal to generate a compensated current signal (block 340). For example, the compensation component may apply the thermal instability compensation factor to the current signal to generate a compensated current signal, as described above.

As further shown in FIG. 3, process 300 may include providing the compensated current signal in association with generation of the laser pulse (block 350). For example, the compensation component may provide the compensated current signal in association with generation of the laser pulse, as described above.

Process 300 may include additional implementations, such as any single implementation or any combination of implementations described below and/or in connection with one or more other processes described elsewhere herein.

In a first implementation, the compensation component generates the compensated current signal based on a logarithmic function.

In a second implementation, alone or in combination with the first implementation, the compensation component generates the compensated current signal based on an exponential decay function.

In a third implementation, alone or in combination with one or more of the first and second implementations, the compensation component generates the compensated current signal based on a linear function.

In a fourth implementation, alone or in combination with one or more of the first through third implementations, the compensation component provides open-loop compensation.

In a fifth implementation, alone or in combination with one or more of the first through fourth implementations, the estimated thermal state is determined using a thermal model.

In a sixth implementation, alone or in combination with one or more of the first through fifth implementations, the thermal model models drive current variation over time of a diode of the diode pump module with respect to temperature of the diode.

In a seventh implementation, alone or in combination with one or more of the first through sixth implementations, the thermal model determines the estimated thermal state further based on a configurable time constant.

In an eighth implementation, alone or in combination with one or more of the first through seventh implementations, the thermal instability compensation factor is calculated further based on a configurable compensation amplitude.

In a ninth implementation, alone or in combination with one or more of the first through eighth implementations, the thermal instability compensation factor is calculated further based on a reference thermal state.

In a tenth implementation, alone or in combination with one or more of the first through ninth implementations, the compensation component uses a thermal model to compensate or correct a drive current over time so as to cause the high-power laser system to provide the output laser pulse having the target output power.

In an eleventh implementation, alone or in combination with one or more of the first through tenth implementations, the period of time is at a start of the laser pulse.

In a twelfth implementation, alone or in combination with one or more of the first through eleventh implementations, the high-power laser system comprises a fiber oscillator and amplification system to generate the output laser pulse using the pump light.

Although FIG. 3 shows example blocks of process 300, in some implementations, process 300 includes additional blocks, fewer blocks, different blocks, or differently arranged blocks than those depicted in FIG. 3. Additionally, or alternatively, two or more of the blocks of process 300 may be performed in parallel.

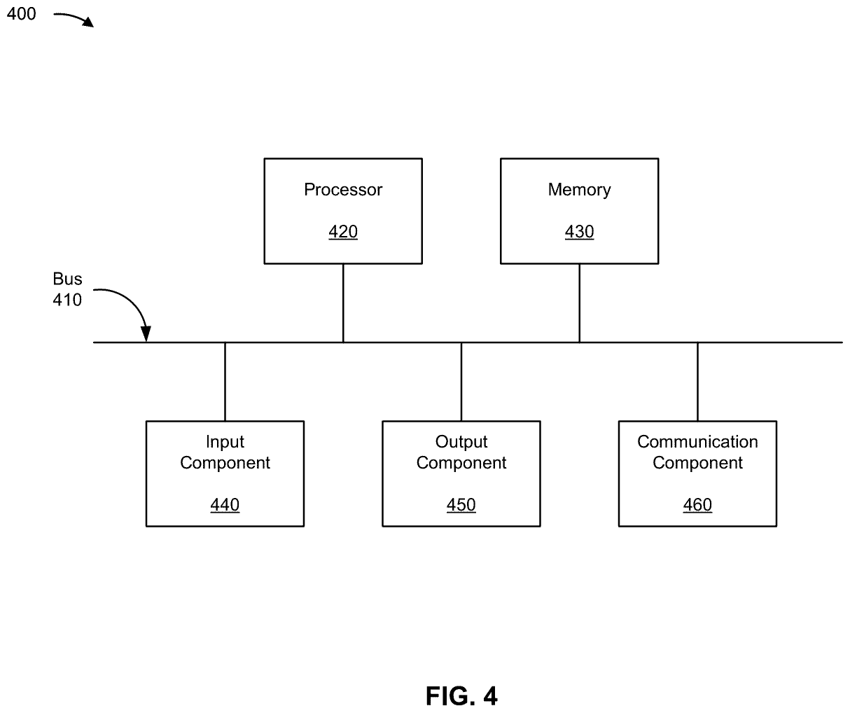

FIG. 4 is a diagram of example components of a device 400 associated with laser power stability control via thermal instability compensation as described herein. The device 400 may correspond to the compensation component 102 and/or one or more components of the compensation component 102 (e.g., the thermal model 202 and/or the compensation calculation component 204). In some implementations, the compensation component 102 and/or the one or more components of the compensation component 102 may may include one or more devices 400 and/or one or more components of the device 400. As shown in FIG. 4, the device 400 may include a bus 410, a processor 420, a memory 430, an input component 440, an output component 450, and/or a communication component 460.

The bus 410 may include one or more components that enable wired and/or wireless communication among the components of the device 400. The bus 410 may couple together two or more components of FIG. 4, such as via operative coupling, communicative coupling, electronic coupling, and/or electric coupling. For example, the bus 410 may include an electrical connection (e.g., a wire, a trace, and/or a lead) and/or a wireless bus. The processor 420 may include a central processing unit, a graphics processing unit, a microprocessor, a controller, a microcontroller, a digital signal processor, a field-programmable gate array, an application-specific integrated circuit, and/or another type of processing component. The processor 420 may be implemented in hardware, firmware, or a combination of hardware and software. In some implementations, the processor 420 may include one or more processors capable of being programmed to perform one or more operations or processes described elsewhere herein.

The memory 430 may include volatile and/or nonvolatile memory. For example, the memory 430 may include random access memory (RAM), read only memory (ROM), a hard disk drive, and/or another type of memory (e.g., a flash memory, a magnetic memory, and/or an optical memory). The memory 430 may include internal memory (e.g., RAM, ROM, or a hard disk drive) and/or removable memory (e.g., removable via a universal serial bus connection). The memory 430 may be a non-transitory computer-readable medium. The memory 430 may store information, one or more instructions, and/or software (e.g., one or more software applications) related to the operation of the device 400. In some implementations, the memory 430 may include one or more memories that are coupled (e.g., communicatively coupled) to one or more processors (e.g., processor 420), such as via the bus 410. Communicative coupling between a processor 420 and a memory 430 may enable the processor 420 to read and/or process information stored in the memory 430 and/or to store information in the memory 430.

The input component 440 may enable the device 400 to receive input, such as user input and/or sensed input. For example, the input component 440 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 450 may enable the device 400 to provide output, such as via a display, a speaker, and/or a light-emitting diode. The communication component 460 may enable the device 400 to communicate with other devices via a wired connection and/or a wireless connection. For example, the communication component 460 may include a receiver, a transmitter, a transceiver, a modem, a network interface card, and/or an antenna.

The device 400 may perform one or more operations or processes described herein. For example, a non-transitory computer-readable medium (e.g., memory 430) may store a set of instructions (e.g., one or more instructions or code) for execution by the processor 420. The processor 420 may execute the set of instructions to perform one or more operations or processes described herein. In some implementations, execution of the set of instructions, by one or more processors 420, causes the one or more processors 420 and/or the device 400 to perform one or more operations or processes described herein. In some implementations, hardwired circuitry may be used instead of or in combination with the instructions to perform one or more operations or processes described herein. Additionally, or alternatively, the processor 420 may be configured to perform one or more operations or processes described herein. Thus, implementations described herein are not limited to any specific combination of hardware circuitry and software.

The number and arrangement of components shown in FIG. 4 are provided as an example. The device 400 may include additional components, fewer components, different components, or differently arranged components than those shown in FIG. 4. Additionally, or alternatively, a set of components (e.g., one or more components) of the device 400 may perform one or more functions described as being performed by another set of components of the device 400.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A laser system, comprising:
a compensation component to:
receive a control signal indicating a target output power of an output laser pulse to be provided by the laser system, and
generate a compensated current signal based on the control signal,
wherein the compensated current signal is to reduce a difference between the target output power of the laser pulse and an actual output power of the laser pulse over a period of time during the laser pulse;
a diode pump drive circuit to generate a drive current based on the compensated current signal;
a diode pump module to generate pump light based on the drive current; and
an optical output to provide the output laser pulse.

2. The laser system of claim 1, wherein the compensation component generates the compensated current signal based on a logarithmic function.

3. The laser system of claim 1, wherein the compensation component generates the compensated current signal based on an exponential decay function.

4. The laser system of claim 1, wherein the compensation component generates the compensated current signal based on a linear function.

5. The laser system of claim 1, wherein the compensation component provides open-loop compensation.

6. The laser system of claim 1, wherein, to generate the compensated current signal, the compensation component is to:
provide a current signal, corresponding to the target output power, as an input to a thermal model,
receive an estimated thermal state associated with the laser system as an output of the thermal model,
calculate a thermal instability compensation factor based on the estimated thermal state, and
apply the thermal instability compensation factor to the current signal to generate the compensated current signal.

7. The laser system of claim 6, wherein the thermal model models drive current variation of a diode of the diode pump module with respect to temperature of the diode.

8. The laser system of claim 6, wherein the thermal model determines the estimated thermal state further based on a configurable time constant.

9. The laser system of claim 6, wherein the thermal instability compensation factor is calculated further based on a configurable compensation amplitude.

10. The laser system of claim 6, wherein the thermal instability compensation factor is calculated further based on a reference thermal state.

11. The laser system of claim 1, wherein the compensation component uses a thermal model to compensate or correct the drive current over time so as to cause the laser system to provide the output laser pulse having the target output power.

12. The laser system of claim 1, wherein the laser system is a high-power laser system.

13. The laser system of claim 1, wherein the period of time is at a start of the laser pulse.

14. The laser system of claim 1, wherein the laser system comprises a fiber oscillator and amplification system to generate the output laser pulse using the pump light.

15. A laser system, comprising:
one or more processors to:
receive a control signal indicating a target output power for a laser pulse, and
generate a compensated current signal based on the control signal,
wherein the compensated current signal is to provide compensation for time-decaying overshoot or undershoot of an actual output power of the laser pulse relative to the target output power of the laser pulse;
a diode pump to generate a pump light based on a drive current that corresponds to the compensated current signal; and
a master oscillator power amplification (MOPA) system to generate the laser pulse using the pump light.

16. The laser system of claim 15, wherein the one or more processors are to generate the compensated current signal based on at least one of a logarithmic function, an exponential decay function, or a linear function.

17. The laser system of claim 15, wherein the one or more processors provide open-loop compensation.

18. The laser system of claim 15, wherein, to generate the compensated current signal, the one or more processors are to:
provide a current signal, corresponding to the target output power, as an input to a thermal model,
receive an estimated thermal state associated with the laser system as an output of the thermal model,
calculate a thermal instability compensation factor based on the estimated thermal state, and
apply the thermal instability compensation factor to the current signal to generate the compensated current signal.

19. The laser system of claim 15, wherein the one or more processors are to use a thermal model to compensate or correct the drive current over time so as to cause the laser system to provide the laser pulse at the target output power.

20. A method, comprising:
receiving, by a compensation component of a high-power laser system, a control signal indicating a target output power of an output laser pulse;
determining, by the compensation component, an estimated thermal state associated with the high-power laser system based on a current signal corresponding to the target output power and using a thermal model;
calculating, by the compensation component, a thermal instability compensation factor based on the estimated thermal state,
wherein the thermal instability compensation factor is calculated in association with providing compensation for output power overshoot or undershoot of the laser pulse over a period of time at a start of the laser pulse;
applying, by the compensation component, the thermal instability compensation factor to the current signal to generate a compensated current signal; and
providing, by the compensation component, the compensated current signal in association with generation of the laser pulse.
